(19) United States
(12) Patent Application Publication
(10) Pub. No.: US 2013/0237010 A1
(43) Pub. Date: Sep. 12, 2013

(54) METHOD FOR MANUFACTURING A GATE-CONTROL DIODE SEMICONDUCTOR MEMORY DEVICE

(71) Applicants: Pengfei Wang, Shanghai (CN); Xi Lin, Shanghai (CN); Qingqing Sun, Shanghai (CN); Wei Zhang, Shanghai (CN)

(72) Inventors: Pengfei Wang, Shanghai (CN); Xi Lin, Shanghai (CN); Qingqing Sun, Shanghai (CN); Wei Zhang, Shanghai (CN)

(21) Appl. No.: 13/554,531

(22) Filed: Jul. 20, 2012

(30) Foreign Application Priority Data
Mar. 11, 2012 (CN) CN 201210061480.3

(51) Int. Cl. H01L 21/336; H01L 21/36

(52) U.S. Cl. 438/104; 257/E21.422; 257/E21.461

(57) ABSTRACT

The present invention belongs to the technical field of semiconductor device manufacturing, and specifically discloses a method for manufacturing a gate-control diode semiconductor storage device. The present invention manufactures gate-control diode semiconductor memory devices through a low-temperature process featuring a simple process, low manufacturing cost and capacity of manufacturing gate-control diode memory devices with a high driving current and small sub-threshold swing. The method for manufacturing a gate-control diode semiconductor memory device proposed by the present invention is especially applicable to the manufacturing of flat panel displays and phase change memories and memory devices based on flexible substrate.

### CROSS-REFERENCE TO RELATED APPLICATION

This application claims priority to Chinese Patent Application No. CN 201210061480.3 filed on Mar. 11, 2012, the entire content of which is incorporated by reference herein.

### BACKGROUND OF THE INVENTION

1. Technical Field

The present invention belongs to the technical field of semiconductor memory device manufacturing, relates to a method for manufacturing a semiconductor memory device, and more especially, to a method for manufacturing a gate-control diode semiconductor memory device.

2. Description of Related Art

Since the proposal of the floating gate memory structure, it has been widely used in the industrial field after several decades' development. But with the continuous reduction of the size of semiconductor devices, the problem of the incapability of minimizing the size of the floating gate memory has been exposed. The structure of the traditional floating-gate transistor is as shown in FIG. 1, including a drain 102 and a source 103 formed in a substrate 101, and polycrystalline silicon gates 105 and 107 formed on the substrate 101, wherein the electrically-connected polycrystalline silicon gate 107 is called “control gate” and the floating polycrystalline silicon gate 105 is called “floating gate”. The floating gate 105 is isolated with the substrate 101 and the control gate 107 through insulation dielectric layers 104 and 106 respectively.

The floating gate memory, of which the working principle is that the transistor threshold voltage is changed according to the fact of whether there are charges stored or how many charges are stored on the floating gate so as to change the external features of the transistor, has now become the basic device structure of on-volatile semiconductor memories. Today, the technology node of the integrated circuit devices is about 45 nm and the leakage current between the source and the drain of MOSFET is increasing rapidly with the decrease of channel length, which seriously affect the maintenance of the electrons on the floating gate. With the repeat of erasing and writing, the channel insulation film will be damaged, which may cause the leakage of the electrons in the floating gate. Moreover, the minimum sub-threshold swing (SS) of the traditional MOSFET is limited to 60 mv/dec, which restricts the opening and closing speed of the transistor.

### BRIEF SUMMARY OF THE INVENTION

The present invention aims at providing a method for manufacturing semiconductor memory devices capable of decreasing the leakage current and the SS value of floating gate memory devices so as to improve the performances thereof.

A method for manufacturing the gate-control diode semiconductor memory device above is provided in the present invention, including the following steps:

form a first kind of insulation film on a p-type silicon substrate;

etch the first kind of insulation film to form an active region window;

deposit a layer of n-type material on the first insulation film and the active region contact hole as an active region which contacts with the p-type subtract at the active region window;

form a second kind of insulation film on the n-type active region;

deposit a first kind of conductive material on the second kind of insulation film and etch it to form a device floating gate;

cover the floating gate to form a third kind of insulation film;

etch the first, second and third kinds of insulation film, form a drain contact window and a source contact window on the two sides of the active region window respectively, thus the p-type subtract at the drain contact hole and the n-type active region at the source contact hole are exposed;

form a second kind of conductive film through deposition and etch it to form a drain electrode, a gate electrode and a source electrode, wherein the drain electrode is located on and fills the drain contract hole, the source electrode is located on and fills the source contact hole, the gate electrode is between the source electrode and the active region window located between the drain and gate electrodes, and the spacing between the gate electrode and the active region window is 20 nm-1 μm.

Further, the p-type active region includes but is not limited to a heavily-doped p-type silicon substrate, a p-type doping region formed in the silicon substrate and ZnO and NiO material which is formed on an insulation substrate and is doped with p-type impurity ions. The first kind of insulation film is of silicon oxide or silicon nitride. The second and third kinds of insulation film is of SiO₂ or high-dielectric constant material such as HfO₂. The second conductive film is of copper, tungsten, aluminum, titanium nitride or tantalum nitride.

Furthermore, the n-type active region is formed of ZnO material and with a thickness of 5-10 nm. The floating gate includes but is not limited to polycrystalline silicon material.

The present invention manufacturing gate-control diode semiconductor memory devices through low-temperature process features simple process, low manufacturing cost and capacity of manufacturing gate-control diode memory devices with high driving current and small sub-threshold swing. The method for manufacturing a gate-control diode semiconductor memory device proposed by the present invention is especially applicable to the manufacturing of flat panel displays and phase change memories and memory devices based on flexible substrate.

### BRIEF DESCRIPTION OF THE SEVERAL VIEWS OF THE DRAWINGS

FIG. 1 is the schematic diagram of the structure of the traditional floating gate memory.

FIGS. 2-7 are the process flow diagrams of an embodiment of the method for manufacturing a gate-control diode semiconductor memory device disclosed in the present invention.

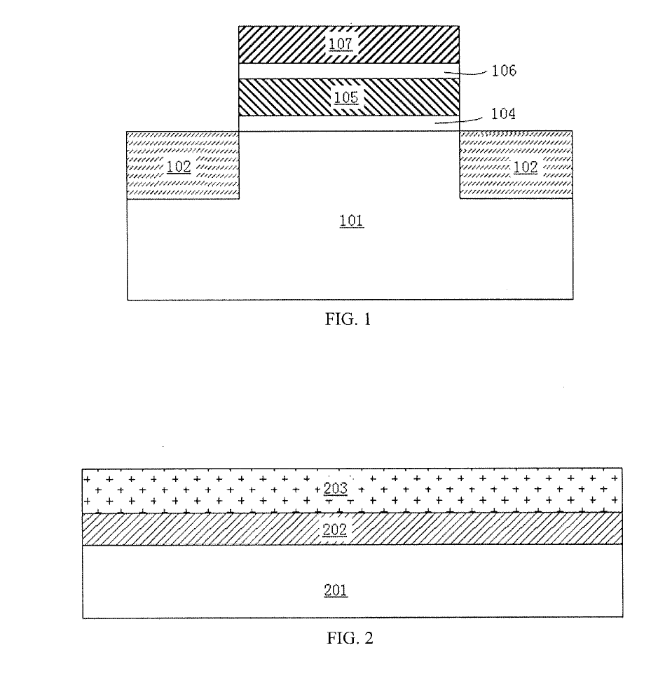

### DETAILED DESCRIPTION OF THE INVENTION

An exemplary embodiment of the present invention is further detailed herein by referring to the drawings. In the drawings, the thicknesses of the layers and regions are either zoomed in or out for the convenience of description, so they shall not be considered as the true size. Although these drawings cannot accurately reflect the true size of the device, they still reflect the relative positions among the regions and composition structures completely, especially the up-down and adjacent relations.

The reference diagrams are the schematic diagrams of the idealized embodiments of the present invention, so the embodiments shown in the present invention shall not be limited to specific shapes in areas shown in the drawings, while they shall include the obtained shapes such as the deviation caused by manufacturing. For instance, curves obtained through etching are often bent or rounded, while in the embodiments of the present invention, they are all presented in rectangles, and what the drawings present is schematic and shall not be considered as the limit to the present invention.

Firstly, prepare a solution with NaOH and water in proportion of 1:20, heat it to 80° C., immerse and rinse a polymide (P1) substrate with the solution for 20 min. Then immerse the P1 substrate in the isopropyl alcohol solution and conduct ultrasonic washing for 10 min. Finally, put the P1 substrate into deionized water, conduct ultrasonic washing for 10 min and blow-dry the P1 substrate surface with N₂.

Deposit a silicon dioxide film 202 on the conditioned P1 substrate 201, then deposit a layer of NiO material doped with p-type impurity ions on the silicon dioxide film 202 and etch the NiO material deposited to form a p-type active region 203, as shown in FIG. 2.

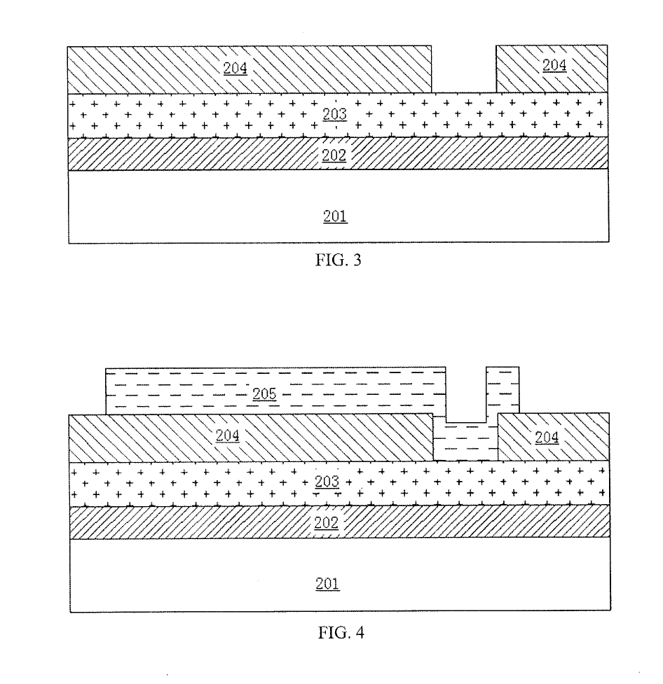

Next, deposit a silicon dioxide film 204 again, then deposit a layer of photoresist, form a pattern through masking film, exposal and development, and etch the silicon dioxide film 204 to form a window, the construction after removing the photoresist is as shown in FIG. 3.

Next, deposit a layer of ZnO material with a thickness of 5-10 nm through the ALD method and etch the ZnO material deposited to form an n-type active region 205, as shown in FIG. 4.

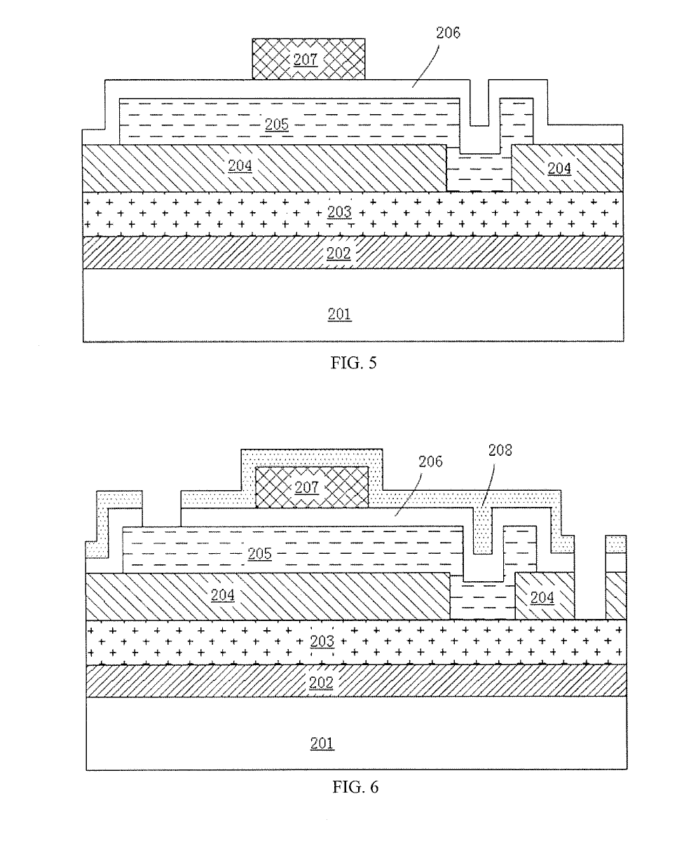

Then deposit a layer of high dielectric constant material 206 such as HfO₂, continue to deposit a layer of polycrystalline silicon on the high dielectric constant material 206 and etch the polycrystalline silicon material deposited to form a device floating gate 207, as shown in FIG. 5.

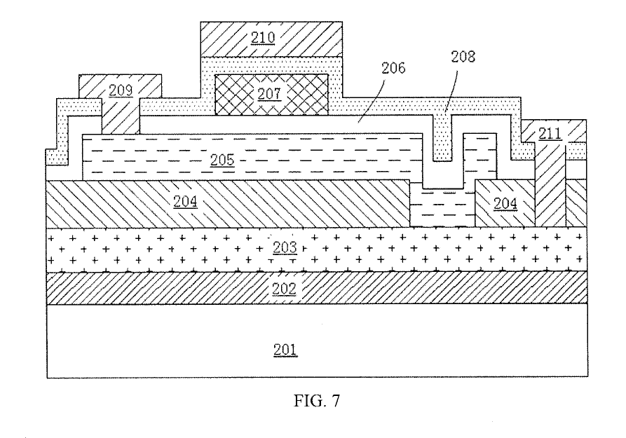

Then deposit an insulation film 208 such as silicon oxide and a layer of photoresist, form a pattern through masking film, exposal and development, and etch the silicon oxide film 208 and the high dielectric constant material 206 and the insulation film 204 to define the positions of the drain and the source, as shown in FIG. 6.

Finally, deposit a metal conductive film such as aluminum and then form a drain electrode 209, a gate electrode 210 and a source electrode 211 through photoetching and etching, as shown in FIG. 7.

As described above, without deviating from the spirit and scope of the present invention, there may be many significantly different embodiments. It shall be understood that the present invention is not limited to the specific embodiments described in the Specification except those limited by the Claims herein.

What is claimed is:

1. A method for manufacturing a gate-control diode semiconductor memory device, characterized in that it includes the following steps:
form a first kind of insulation film on a p-type silicon substrate;
etch the first kind of insulation film to form an active region window;
deposit a layer of n-type material on the first insulation film and the active region contact hole as an active region which contacts with the p-type subtract at the active region window;
form a second kind of insulation film on the n-type active region;
deposit a first kind of conductive material on the second kind of insulation film and etch it to form a device floating gate;
cover the floating gate to form a third kind of insulation film;
etch the first, second and third kinds of insulation film, form a drain contact window and a source contact window on the two sides of the active region window respectively, thus the p-type subtract at the drain contact hole and the n-type active region at the source contact hole are exposed;
form a second kind of conductive film through deposition and etch it to form a drain electrode, a gate electrode and a source electrode, wherein the drain electrode is located on and fills the drain contract hole, the source electrode is located on and fills the source contact hole, the gate electrode is between the source electrode and the active region window located between the drain and gate electrodes, and the spacing between the gate electrode and the active region window is 20 nm-1 μm.

2. The method for manufacturing a gate-control diode semiconductor memory device according to claim 1, characterized in that, the p-type active region includes a p-type silicon substrate, a p-type doping region formed on the silicon substrate and ZnO or NiO material which is formed on an insulation substrate and doped with p-type impurity ions.

3. The method for manufacturing a gate-control diode semiconductor memory device according to claim 1, characterized in that the first kind of insulation film is of silicon oxide or silicon nitride.

4. The method for manufacturing a gate-control diode semiconductor memory device according to claim 1, characterized in that the second and third kinds of insulation film are of SiO₂ or HfO₂.

5. The method for manufacturing a gate-control diode semiconductor memory device according to claim 1, characterized in that the n-type active region is of ZnO material and with a thickness of 5-10 nm.

6. The method for manufacturing a gate-control diode semiconductor memory device according to claim 1, characterized in that the floating gate is of polycrystalline silicon material.

7. The method for manufacturing a gate-control diode semiconductor memory device according to claim 1, characterized in that the second kind of conductive film is of copper, tungsten, aluminum, titanium nitride or tantalum nitride.
